(19) United States
(12) Patent Application Publication
(10) Pub. No.: US 2025/0215562 A1
(43) Pub. Date: Jul. 3, 2025

(54) EXHAUST STRUCTURE, EXHAUST SYSTEM, PROCESSING APPARATUS, AND METHOD OF MANUFACTURING SEMICONDUCTOR DEVICE

(71) Applicant: KOKUSAI ELECTRIC CORPORATION, Tokyo (JP)

(72) Inventors: Masakazu SAKATA, Toyama-shi (JP); Ryosuke TAKAHASHI, Toyama-shi (JP)

(73) Assignee: KOKUSAI ELECTRIC CORPORATION, Tokyo (JP)

(21) Appl. No.: 19/080,439

(22) Filed: Mar. 14, 2025

Related U.S. Application Data
(63) Continuation of application No. PCT/JP2023/013202, filed on Mar. 30, 2023.

(30) Foreign Application Priority Data
Sep. 16, 2022 (JP) 2022-148369

(51) Int. Cl. C23C 16/44; C23C 16/52

(52) U.S. Cl. CPC C23C 16/4412; C23C 16/4408; C23C 16/52

(57) ABSTRACT

There is provided a structure that includes: an exhaust pipe configured to exhaust an atmosphere of a process chamber; a regulator installed on the exhaust pipe and configured to regulate a pressure inside the process chamber; a vent pipe installed to be branched off from the exhaust pipe at an upstream of the regulator; a pressure detector installed on the exhaust pipe at a downstream of the regulator and configured to detect the pressure inside the exhaust pipe; and a branch pipe including an opening/closing part configured to operate in response to a signal from the pressure detector, the branch pipe branching off from the exhaust pipe at the downstream of the regulator, wherein the branch pipe is configured to be connected to the vent pipe.

### CROSS-REFERENCE TO RELATED APPLICATION

This application is a Bypass Continuation Application of PCT International Application No. PCT/JP2023/013202, filed on Mar. 30, 2023, and designating the United States, the international application being based upon and claiming the benefit of priority from Japanese Patent Application No. 2022-148369, filed on Sep. 16, 2022, the entire content of which is incorporated herein by reference.

### TECHNICAL FIELD

The present disclosure relates to an exhaust structure, an exhaust system, a processing apparatus, and a method of manufacturing a semiconductor device.

### BACKGROUND

In a substrate processing apparatus (hereinafter also referred to as a semiconductor manufacturing apparatus) used in a semiconductor device manufacturing process, for example, several tens of flow rate controllers are installed in one apparatus, and an efficient setup operation for these flow rate controllers is described in the related art. Meanwhile, in an operation of setting up a flow rate controller provided in an exhaust system, it may be difficult to confirm a vacuum state, for example, whether a downstream pump or valve is within a customer's range. Therefore, an exhaust pipe may be over-pressurized by supplying a gas to a pipe of an exhaust system without noticing that a valve is closed. Thus, in the related art, while over-pressurization protection is generally performed inside a reaction container, over-pressurization protection for an exhaust pipe is becoming necessary.

### SUMMARY

Some embodiments of the present disclosure provide a structure capable of protect a pipe of an exhaust system against over-pressurization.

According to embodiments of the present disclosure, there is provided an exhaust structure, including: an exhaust pipe configured to exhaust an atmosphere of a process chamber; a regulator installed on the exhaust pipe and configured to regulate a pressure inside the process chamber; a vent pipe installed to be branched off from the exhaust pipe at an upstream of the regulator; a pressure detector installed on the exhaust pipe at a downstream of the regulator and configured to detect the pressure inside the exhaust pipe; and a branch pipe including an opening/closing part configured to operate in response to a signal from the pressure detector, the branch pipe branching off from the exhaust pipe at a downstream of the regulator, and the branch pipe is configured to be connected to the vent pipe.

### BRIEF DESCRIPTION OF DRAWINGS

The accompanying drawings, which are incorporated in and constitute a part of the specification, illustrate embodiments of the present disclosure.

FIG. 1 is a diagram showing one configuration example of a process furnace of a substrate processing apparatus preferably used in embodiments of the present disclosure.

FIG. 2 is a block diagram showing one configuration example of a control module of the substrate processing apparatus preferably used in the embodiments of the present disclosure.

FIG. 3 is a diagram showing one configuration example of an exhaust system of the substrate processing apparatus preferably used in the embodiments of the present disclosure.

FIG. 4 is a diagram explaining an adjustment sequence for components constituting the substrate processing apparatus preferably used in the embodiments of the present disclosure.

FIG. 5 is a diagram showing one example of the influence of an over-pressurized state of the exhaust system on the apparatus.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

Hereinafter, embodiments of the present disclosure will be described with reference to the drawings. All drawings used in the following description are schematic, and the dimensional relationship of respective elements, the ratio of respective elements, and the like shown in the drawings do not necessarily match the actual ones. Furthermore, the dimensional relationship of respective elements, the ratio of respective elements, and the like do not necessarily match between a plurality of drawings. In addition, throughout the plurality of drawings, substantially the same elements are designated by the same reference numerals. Each element will be described in respect of the drawing in which the element appears first, and the description thereof will be omitted in respect of subsequent drawings unless particularly necessary. Unless otherwise specified in the specification, each element is not limited to one, and may be multiple.

### (Process Furnace)

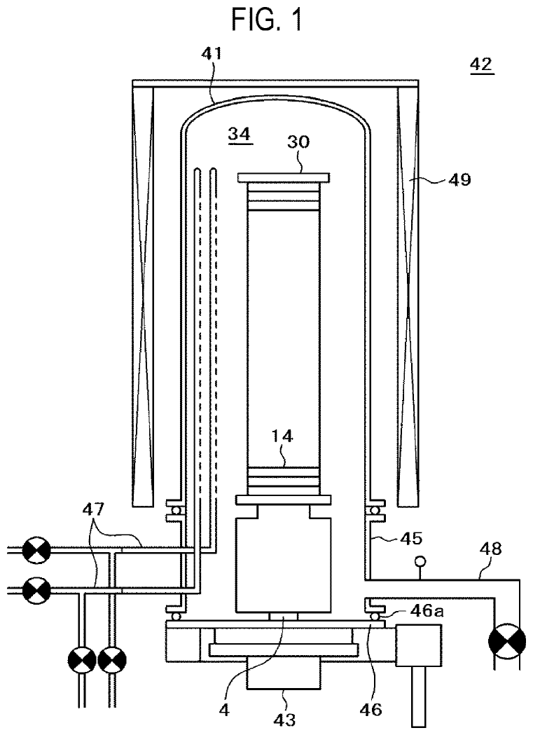

FIG. 1 illustrates a process furnace 42 of a substrate processing apparatus preferably used in this embodiment. In this embodiment, the substrate processing apparatus is configured as a vertical substrate processing apparatus (hereinafter referred to as a processing apparatus) that performs a substrate processing process such as a heat treatment or the like as one manufacturing process in a semiconductor device manufacturing method.

The process furnace 42 includes a reaction tube 41. The reaction tube 41 is made of a heat-resistant nonmetallic material such as quartz (SiO₂) or silicon carbide (SiC), and has a cylindrical shape with a closed upper end and an open lower end.

A process chamber 34 is formed inside the cylinder of the reaction tube 41. A boat 30 serving as a substrate holder (substrate holding tool) is inserted from below into the process chamber 34, and wafers 14 as substrates held in a horizontal posture by the boat 30 are accommodated in the process chamber 34 in a vertically aligned state in multiple stages. By rotating a rotary shaft 44 by a rotator 43, the boat 30 accommodated in the process chamber 34 is configured to be rotatable with the wafers 14 mounted thereon while maintaining the process chamber 34 airtight.

A manifold 45 is disposed concentrically with the reaction tube 41 below the reaction tube 41. The manifold 45 is made of a metal material such as stainless steel or the like, and has a cylindrical shape with an open upper end and an open lower end. The reaction tube 41 is supported vertically from the lower end side by the manifold 45. That is, the reaction tube 41 forming the process chamber 34 is vertically supported via the manifold 45 to form the process furnace 42. The lower end of the manifold 45 is configured to be airtightly sealed by a seal cap 46 when a boat elevator (not shown) rises. A sealing member 46a such as an O-ring or the like that airtightly seals the process chamber 34 is provided between the lower end of the manifold 45 and the seal cap 46.

In addition, a gas introduction pipe 47 for introducing a purge gas, a purge gas, and the like into the process chamber 34 and an exhaust pipe 48 for exhausting the gases (atmosphere) in the process chamber 34 are connected to the manifold 45.

A heater unit 49 serving as a heating means (heating mechanism) is arranged around the outer periphery of the reaction tube 41 concentrically with the reaction tube 41. The heater unit 49 is configured to heat the process chamber 34 so that the process chamber 34 has a uniform or predetermined temperature distribution throughout the process chamber 34.

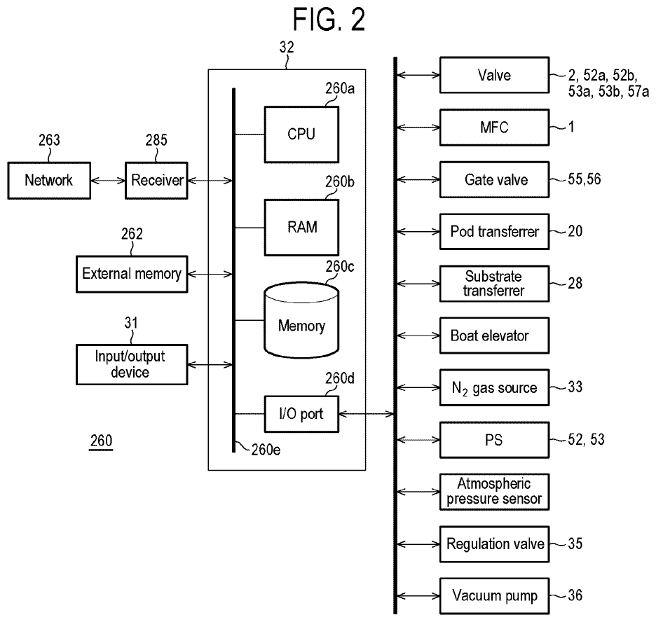

FIG. 2 shows one configuration example of a control system of the substrate processing apparatus including an input/output device 31 and the control part 32. A controller 260 is configured to include at least the input/output device 31 and the control part 32.

The control part 32 is configured as a computer including a CPU (Central Processing Unit) 260a, a RAM (Random Access Memory) 260b, a memory device 260c, and an I/O port 260d. The RAM 260b, the memory device 260c, and the I/O port 260d are configured to be able to exchange data with the CPU 260a via an internal bus 260e.

The CPU 260a as a calculation part is configured to read a control program from the memory device 260c and execute the read program, and is configured to read files from the memory device 260c in response to the input of an operation command from the input/output device 31. The CPU 260a is also configured to be capable of calculating calculation data by comparing and calculating a set value inputted from a receiving part 285 with the files and control data stored in the memory device 260c. The RAM 260b is configured as a memory area (work area) in which the programs, calculation data, processing data, and the like read by the CPU 260a are temporarily held.

The memory device 260c is composed of, for example, a flash memory, an HDD (Hard Disk Drive), or the like. The memory device 260c stores a control program for controlling the operation of the substrate processing apparatus, various files, data sensed by each sensor, and the like, and also readably stores calculation data and processing data generated in the process of setting a process recipe used for processing the wafers 14. The various files include screen files such as an editing screen for editing a recipe and a setting screen for setup, a sequence for adjusting a component to be adjusted that is used by switching a plurality of switches according to the gas type, a process recipe in which the procedure and conditions of substrate processing are written, a recipe for transferring the wafers 14, and the like.

An edit screen for creating an adjustment sequence under the same conditions as those used for initialization and a selection screen for selecting a component to be adjusted are displayed on the operation screen of the input/output device 31. For example, the input/output device 31 formed of a touch panel or the like is configured to be connectable to an external memory device 262. Furthermore, a network 263 is connectable to the controller 260 through a receiving part 285. This means that the controller 260 can also be connected to a higher-level device such as a host computer present on the network 263. Therefore, if the input/output device 31 exists on the network 263, it can be connected to the controller 260. In other words, the input/output device 31 may be located away from the substrate processing apparatus without being limited to the above-described embodiment.

Hereinafter, each file including the process recipe, the control program, and the like may be collectively and simply referred to as a program. When the word “program” is used in this specification, it may include only a process recipe, only a control program, or both.

The controller 260 is not limited to being configured as a dedicated computer, and may be configured as a general-purpose computer. For example, the controller 260 according to the embodiments can be configured by preparing an external memory device 262 storing the above-mentioned program, and installing the program in a general-purpose computer using the external memory device 262. The external memory device 262 is, for example, a magnetic tape, a magnetic disk such as a flexible disk or a hard disk, an optical disk such as a CD or a DVD, a magneto-optical disk such as an MO, or a semiconductor memory such as a USB memory or a memory card.

The means for supplying the program to the computer is not limited to supplying the program via the external memory device 262. For example, the program may be supplied without going through the external memory device 262 by using a communication means such as a network 263 (the Internet or a dedicated line).

The memory device 260c and the external memory device 262 are configured as computer-readable recording media. Hereinafter, these will be collectively and simply referred to as recording media. When the term “recording medium” is used in this specification, it may include only the memory device 260c, only the external memory device 262, or both.

Next, an operation procedure for processing wafers 14 as one of processes of manufacturing a semiconductor device using the substrate processing apparatus according to the embodiments will be described with reference to FIGS. 1 and 2.

### (Pod Transfer Process)

When processing wafers 14 in the substrate processing apparatus, a pod containing a plurality of wafers 14 is first held on the pod stage. The pod is then transferred from the pod stage to a rotary pod shelf by a pod transfer device 20.

### (Wafer Supply Process)

Then, the pod held on the rotary pod shelf is transferred to a pod opener by the pod transfer device 20. A pod lid is then opened by the pod opener, and the number of wafers 14 contained in the pod is detected by a substrate number detector.

### (Pre-Loading Delivery Process)

After the pod lid is opened, a substrate transfer machine 28 located in a delivery chamber takes out the wafer 14 from the pod. The unprocessed wafer 14 taken out from the pod is then delivered to a boat 30 located in the delivery chamber just like the substrate transfer machine 28. In other words, the substrate transfer machine 28 performs a wafer charging operation in the delivery chamber to load the unprocessed wafer 14 into the boat 30 before loading it into the process chamber 34. As a result, the boat 30 holds a plurality of wafers 14 in a stacked state with a gap between them in the vertical direction.

### (Loading Process)

After the wafer charging operation, the boat 30 holding the unprocessed wafers 14 is loaded into the process chamber 34 by raising the boat elevator (boat loading). In other words, the boat elevator is operated to load the boat 30 holding the unprocessed wafers 14 from the transfer chamber into the process chamber 34. Thus, the seal cap 46 seals the lower end of the manifold 45 via the sealing member 46a.

### (Processing Process)

After the boat loading, a predetermined process is performed on the unprocessed wafers 14 held by the boat 30 that has been brought into the process chamber 34. Specifically, the exhaust pipe 48 is used to evacuate the process chamber 34 to a desired pressure (vacuum level). The heater unit 49 is used to heat the process chamber 34, and the rotator 43 is operated to rotate the boat 30, which in turn rotates the wafers 14. Furthermore, a precursor gas, a purge gas, and the like are supplied into the process chamber 34 through the gas introduction pipe 47. As a result, a thin film is formed on the surface of each of the unprocessed wafers 14 held by the boat 30, for example, by using a thermal decomposition reaction or a chemical reaction.

After the thin film formation on the surface of each of the wafers 14 is completed, the heating by the heater unit 49 is stopped, and the temperature of the processed wafers 14 is lowered to a predetermined temperature. Then, after a preset time has elapsed, the supply of the gases to the process chamber 34 is stopped, and the supply of an inert gas to the process chamber 34 is started. Thus, the inside of the process chamber 34 is replaced with the inert gas, and the pressure inside the process chamber 34 is returned to the atmospheric pressure. Furthermore, during or after the process chamber 34 is returned to the atmospheric pressure, the rotation of the boat 30 by the rotator 43 is also stopped.

### (Unloading Process)

Then, the boat elevator is lowered to lower the seal cap 46 and open the lower end of the manifold 45, and the boat 30 holding the processed wafers 14 is unloaded from the lower end of the manifold 45 to the outside of the process chamber 34 (boat unloading).

### (Post-Unloading Delivery Process)

After the wafers 14 in the waiting boat 30 are cooled to a predetermined temperature (e.g., about the room temperature), the substrate transfer machine 28 arranged in the delivery chamber removes the wafers 14 from the boat 30. Then, a wafer discharge operation is performed in which the processed wafers 14 removed from the boat 30 are transferred to and stored in an empty pod held on the pod opener. Thereafter, the pod transfer device 20 transfers the pod containing the processed wafers 14 onto the rotary pod shelf or the pod stage. In this way, a series of processing operations in the substrate processing process performed by the substrate processing apparatus is completed.

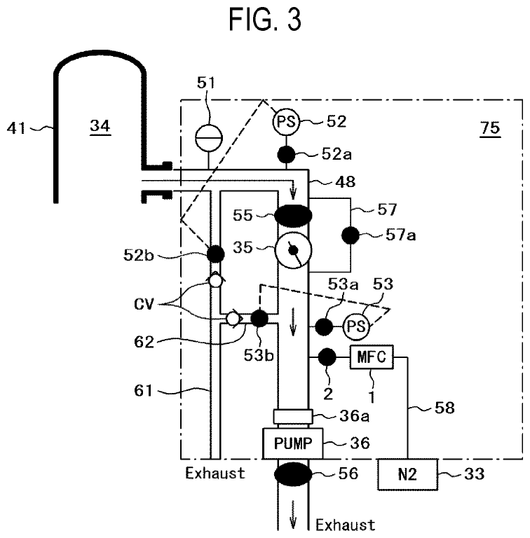

FIG. 3 shows one configuration example of an exhaust system of the substrate processing apparatus used in this embodiment. The portion enclosed by the one-dot chain line in FIG. 3 is called an exhaust box 75.

As shown in FIG. 3, on the exhaust pipe 48 as a main exhaust line, a pressure sensor 51 as a pressure sensing part, a pressure switch 52 as a pressure detecting part, a gate valve 55 as a first opening/closing part, a regulation valve 35, a pressure switch 53 as a pressure detecting part, and a vacuum pump 36 as an exhaust device via a bellows 36a are installed sequentially from the upstream side. In the drawings, the pressure switches 52 and 53 are sometimes written as “PS”, and the vacuum pump 36 is sometimes written as “PUMP”. Furthermore, a gate valve 56 as a second opening/closing part is provided on the secondary side (downstream side) of the vacuum pump 36. The pressure sensor 51 is a pressure sensor that senses the pressure inside the process chamber 34. The pressure switch 52 is a first pressure switch that detects whether the pressure inside the process chamber 34 exceeds the atmospheric pressure. The gate valve 55 is a shutoff valve that shuts off the flow path in the exhaust pipe 48. The regulation valve 35 is an APC (Auto Pressure Controller) valve as a pressure regulator. The pressure switch 53 is a second pressure switch that detects whether the pressure inside the exhaust pipe 48 at a downstream of the regulation valve 35 exceeds the atmospheric pressure. The bellows 36a is a bellows-shaped flexible pipe that can expand and contract. The vacuum pump 36 reduces the pressure inside the process chamber 34. The gate valve 56 is a shutoff valve that stops evacuation.

The gate valve 55 can evacuate the process chamber 34 and stop the evacuation of the process chamber 34 by being opened and closed in a state in which the regulation valve 35 and the gate valve 56 are in an open state and the vacuum pump 36 is in operation. The regulation valve 35 is configured to evacuate the process chamber 34 and stop the evacuation of the process chamber 34 by being opened and closed in a state in which the gate valve 55 and the gate valve 56 are in an open state and the vacuum pump 36 is in operation. The regulation valve 35 is further configured to regulate the pressure inside the process chamber 34 by adjusting the valve opening degree based on the pressure information sensed by the pressure sensor 51 in a state in which the gate valve 55 and the gate valve 56 are in an open state and the vacuum pump 36 is in operation.

A vent pipe 61 as an atmospheric pressure release line (over-pressurization protection line) for protecting the process chamber 34 against over-pressurization is provided to branch off from the exhaust pipe 48 at an upstream of the regulation valve 35 (gate valve 55) for adjusting the pressure inside the process chamber 34. The vent pipe 61 is provided with a valve 52b that operates from a closed state to an open state upon receiving a signal from the pressure switch 52, and a check valve CV as a valve part for preventing backflow. The vent pipe 61 is connected to the external exhaust (denoted as “Exhaust” in FIG. 3).

In addition, a branch pipe 57 serving as a slow exhaust line for slowly evacuating the process chamber 34 is provided so as to bypass the gate valve 55 and the regulation valve 35, and an air valve 57a serving as a fourth opening/closing valve is provided on the branch pipe 57.

A branch pipe 62 serving as a release line (over-pressurization protection line) is provided so as to branch off from the exhaust pipe 48 at a downstream of the regulation valve 35 that regulates the pressure inside the process chamber 34. The branch pipe 62 is provided with a valve 53b serving as a third opening/closing part that operates from a closed state to an open state upon receiving a signal from the pressure switch 53, and a check valve CV serving as a valve part for preventing backflow. The branch pipe 62 is connected to the vent pipe 61.

In addition, the above-mentioned branch pipe 62 and the purge pipe 58 as a purge gas line are provided so as to branch off from the exhaust pipe 48 between the gate valve 55 and the gate valve 56, specifically, the exhaust pipe 48 at the downstream of the regulation valve 35 that regulates the pressure inside the process chamber 34 and upstream of the vacuum pump 36. The upstream side of the purge pipe 58 is connected to a nitrogen (N₂) gas source (indicated as “N2” in FIG. 3) 33 as an inert gas source. The purge pipe 58 is provided with an MFC (Mass Flow Controller) 1 as a flow rate controller from the upstream side, and is provided so that the inert gas whose flow rate is controlled via the valve 2 can be introduced regardless of the state of the valve 53b, the gate valve 55, and the gate valve 56. The purge pipe 58 may be provided with a heating part (not shown) for heating the inert gas.

As described above, according to this embodiment, there is provided an exhaust pipe structure that includes the exhaust pipe 48 for exhausting the atmosphere in the process chamber 34, the pressure switch 53 provided on the exhaust pipe 48 to detect the pressure inside the exhaust pipe 48, and the branch pipe 62. In this regard, the branch pipe 62 includes the valve 53b configured to operate upon receiving a signal from the pressure switch 53, and the check valve CV configured to prevent backflow to the exhaust pipe 48. This exhaust pipe structure can protect the exhaust pipe (pipe of the exhaust system) against over-pressurization.

In this embodiment, when the pressure switch 53 detects a preset pressure (e.g., the atmospheric pressure), the valve 53b is switched from a closed state to an open state in response to a signal from the pressure switch 53. Furthermore, the branch pipe 62 is configured to be connected to the vent pipe 61. With this configuration, the atmosphere in the exhaust pipe 48 can be exhausted to the vent pipe 61 via the valve 53b, so that the exhaust pipe (pipe of the exhaust system) can be protected from over-pressurization.

In this embodiment, the above-mentioned exhaust pipe structure including the branch pipe 62 and the pressure switch 53 is provided on the exhaust pipe 48 between the gate valve 55 (regulation valve 35) and the gate valve 56 (vacuum pump 36). In this case, the valve 53b is switched from a closed state to an open state upon receiving a signal from the pressure switch 53, so that the atmosphere in the exhaust pipe 48 can be allowed to flow to the branch pipe 62 before the pressure inside the exhaust pipe 48 becomes higher than the atmospheric pressure (over-pressurization). Thus, the atmosphere in the exhaust pipe 48 can be released to the branch pipe 62 without deforming the bellows 36a, and the exhaust pipe (pipe of the exhaust system) can be protected from over-pressurization. Furthermore, since there is no need to replace components due to deformation of the bellows 36a, it is possible to suppress a decrease in the apparatus operating rate due to maintenance such as component replacement or the like.

Conventionally, even if the bellows 36a absorbs the over-pressurization, maintenance (e.g., replacement of the bellows 36a) is still required. Therefore, there is concern about a decrease in the operating rate of the apparatus. However, in this embodiment, the gas (or gaseous substance) in the exhaust pipe 48 between the gate valve 55 (regulation valve 35) and the gate valve 56 (vacuum pump 36) is released to the branch pipe 62, so that the exhaust pipe 48 can be protected against over-pressurization. As a result, the bellows 36a is not deformed because the gas is exhausted from the branch pipe 62 before the exhaust pipe 48 becomes over-pressurized. Therefore, if the reason is minor (e.g., the gate valve 56 is closed), the process can be continued without maintenance when the error caused by the over-pressurization of the exhaust pipe 48 is eliminated. Therefore, it is possible to suppress the decrease in the operating rate of the apparatus.

Furthermore, in this embodiment, the gas can be exhausted from the branch pipe 62 before the exhaust pipe 48 between the gate valve 55 (regulation valve 35) and the gate valve 56 (vacuum pump 36) becomes over-pressurized. This reduces the influence of over-pressurization on the regulation valve 35. For example, it is possible to reduce the risk of damage to the regulation valve 35. Furthermore, the effect of reducing the influence of over-pressurization can be expected not only for the bellows 36a but also for the components that constitute the vacuum pump 36.

Furthermore, in this embodiment, there is provided a purge pipe 58 connected to the exhaust pipe 48 and configured to be able to supply a predetermined gas (e.g., an inert gas) to the exhaust pipe 48. The branch pipe 62 and the purge pipe 58 are both connected to the exhaust pipe 48, but are spaced apart from each other. Therefore, it is possible to expect a purge effect by the purge gas supplied from the purge pipe 58 to the exhaust pipe 48. In addition, the purge pipe 58 is preferably installed at a downstream of the branch pipe 62, so that a greater purging effect can be expected.

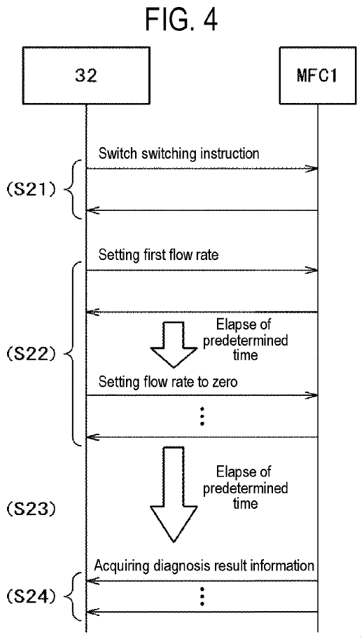

Next, there will be shown an example of a diagnostic sequence between the control part 32 and each MFC 1 corresponding to FIG. 4. When there are multiple MFCs, the control part 32 performs this adjustment sequence for each designated MFC.

At the start of adjustment, the vacuum pump 36 is turned on, and the gate valve 55 is closed to evacuate the inside of the exhaust pipe 48. All of these operations are performed according to digital I/O instructions from the control part 32.

(S21) In this step, the control part 32 simultaneously issues an instruction to switch the switch of the MFC1 to be adjusted to an N₂ gas, thereby switching the switch of the MFC1 to the N₂ gas. This is because initialization is performed with the N₂ gas, which is the basis for the initial diagnostic check. In this regard, the switch means the registration number of one gas of the MFC that corresponds to multiple gases. By switching this switch, the MFC becomes able to control the gas set to the specified number among multiple gases registered in advance. If the MFC is originally dedicated to the N₂ gas, or if the N₂ gas is specified, this step may be omitted.

(S22) After (S21) is completed, the flow rate in the MFC1 is adjusted to a predetermined flow rate previously determined as a first flow rate. After a predetermined time has elapsed, the flow rate in the MFC to be diagnosed is further adjusted to a second flow rate (zero flow rate). Specifically, the N₂ gas source 33 is turned on and the valve 2 is opened in response to an instruction from the control part 32. For example, the flow rate in the MFC1 is set to 20%. The MFC1 uses the coefficient of the inert gas and adjusts the opening degree of the valve based on the value of a flow rate conversion pressure sensor in the MFC1 to control the flow rate to 20%. The flow rate in the MFC1 may be controlled to the predetermined flow rate in this manner and may wait for a predetermined time, such as 10 seconds, at the predetermined flow rate, or may be set to zero as soon as the flow rate converges to the predetermined flow rate. For example, the set flow rate may be set to 20%, 40%, 60%, 80%, and 100%.

(S23) The control part 32 waits for a predetermined time and confirms the end of the initial diagnostic check as a component check (the zero flow rate in the MFC). Since the time when the flow rate will become zero can be predicted in advance, the component check may be completed when the flow rate in the MFC1 has increased from the second flow rate (zero flow rate) for a predetermined time. In this way, the control part 32 closes the valve in the target MFC1 (or adjusts the set flow rate to 0%) and confirms the time when the component check completion time (convergence time) when the flow rate converges to zero.

(S24) The control part 32 simultaneously acquires component check result information (e.g., time) from the MFC 1. The MFC 1 acquires check result information (diagnosis result information) triggered by a predetermined flow rate (zero flow rate) and compares it with the initialization information. The MFC 1 may also be configured to output check result information triggered by a predetermined time. Specifically, the control part 32 acquires the pressure indicating a pressure change, the time at which the flow rate reaches or converges to zero, the temperature, and the like as check result information after convergence to a zero flow rate or after the lapse of a predetermined time such as three seconds.

If the acquired component check result information, for example, the arrival time, is not within a preset time range, the control part 32 generates an alarm, performs a predetermined error processing process, and terminates the diagnostic flow. For example, if this component check error occurs, the MFC is replaced with a new one, and then the adjustments (initial diagnostic checks) from S21 to S24 described above are performed in the same manner.

In FIG. 4, the switching of this switch is performed by the control part 32. However, the switch may be configured to be switched manually. According to this embodiment, it is possible to reduce the time required to determine whether or not there is an initial defect in the component to be adjusted (MFC1) when the apparatus is started up.

In this case, since the valve interlock is released in advance to perform the adjustment operation (S21 to S24) of the MFC1, the purge pipe 58 is installed so as to be able to introduce the flow-rate-controlled inert gas regardless of the states of the valve 53b, the gate valve 55, and the gate valve 56. Therefore, the inert gas whose flow rate is controlled by the MFC1 installed in the purge pipe 58 can be introduced into the flow path in the exhaust pipe 48 via the valve 2 while closing the valve 53b, the gate valve 55, and the gate valve 56.

The gate valve 56 is arranged, for example, at a position away from the vacuum pump 36. Therefore, even if the gate valve 56 is in a closed state, the flow rate of the inert gas used in the adjustment operation of the MFC1 (S21 to S24) is not so high that the adjustment operation of the MFC1 (S21 to S24) is not affected.

If the adjustment takes a long time, for example if the flow rate does not converge to a predetermined flow rate or zero within a preset time, a large amount of inert gas may be unknowingly allowed to flow. In this case, the exhaust pipe 48 at a downstream of the gate valve 55 and at an upstream of the gate valve 56 may become over-pressurized.

In this way, even if the exhaust pipe 48 at the downstream of the gate valve 55 becomes over-pressurized due to the above-mentioned adjustment operation (S21 to S24) of the MFC1, according to this embodiment, the pressure switch 53 detects that the pressure inside the exhaust pipe 48 is equal to or higher than the atmospheric pressure and opens the valve 53b from the closed state. As a result, the atmosphere in the exhaust pipe 48 can be released from the branch pipe 62 to the vent pipe 61 by opening the valve 53b. Therefore, the influence of the over-pressurization of the exhaust pipe 48 on the bellows 36a can be suppressed, and the time wasted in the setup operation due to the maintenance for replacement can be reduced.

In this regard, the setup operation according to the embodiments includes not only the above-mentioned initial diagnostic check of the components constituting the exhaust line, but also an installation operation of the housing of the substrate processing apparatus, a wiring operation of the electrical equipment, and a connection operation of the gas supply line and the exhaust line. The setup operation further includes not only an operation check (component check) operation such as an initial diagnostic check of the components constituting the gas supply line, but also a transfer check operation for executing a recipe for transferring the wafers 14 stored in the substrate storage container (pod) to the process chamber 34, and a leak check operation for executing a leak check recipe for depressurizing the process chamber 34 to a predetermined pressure. The transfer check operation may include an operation of loading the wafers 14 into the boat 30. Furthermore, the transfer check operation includes a baking operation for executing a recipe for annealing the reaction tube 41 constituting the process chamber 34. This baking operation is configured to be performed at a temperature higher than the temperature at which the processing is performed in the process chamber 34 without loading not only the wafers 14 but also the boat 30 into the process chamber 34. In addition, in order to shorten the setup operation time, the transfer check operation and the baking operation can be performed in parallel.

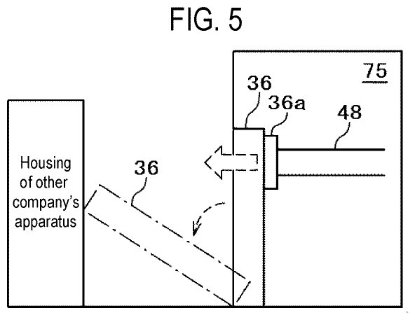

In this manner, according to the embodiments described above, it is possible to prevent an accident that, as shown in FIG. 5, the bellows 36a is expanded due to the over-pressurization of the exhaust side pipe (exhaust pipe 48), thereby acting a force in the direction of the arrow and pushing over the vacuum pump 36.

### OTHER EMBODIMENTS

Although the embodiments of the present disclosure are specifically described above, the present disclosure is not limited to the above-described embodiments and may be modified in various ways without departing from the spirit of the present disclosure.

In the above-described embodiment, the inert gas is an N₂ gas, but the inert gas is not limited to the N₂ gas. Alternatively, a rare gas such as an Ar gas, a He gas, a Ne gas, or a Xe gas may be used. In this case, however, a rare gas source needs to be prepared.

In addition, the processing performed by the substrate processing apparatus may be, for example, a film-forming process, a process for forming an oxide film or a nitride film, a process for forming a film containing a metal, or the like. Furthermore, the specific content of the substrate processing is not important, and the present disclosure can be suitably applied not only to the above-mentioned processes such as the film-forming process or the like, but also to other substrate processing processes such as an annealing process, an oxidation process, a nitriding process, a diffusion process, and a lithography process.

Furthermore, the present disclosure can be suitably applied to other substrate processing apparatuses, such as an annealing apparatus, an oxidation apparatus, a nitriding apparatus, an exposure apparatus, a coating apparatus, a drying apparatus, a heating apparatus, a processing apparatus using plasma, and the like. In addition, the present disclosure may use these apparatuses in combination.

In addition, although the semiconductor manufacturing process has been described in this embodiment, the present disclosure is not limited thereto. For example, the present disclosure can be applied to substrate processing processes such as, for example, a liquid crystal device manufacturing process, a solar cell manufacturing process, a light emitting device manufacturing process, a glass substrate processing process, a ceramic substrate processing process, and a conductive substrate processing process.

In addition, it is possible to replace a part of the configurations of one embodiment with the configuration of another embodiment, and it is also possible to add the configuration of another embodiment to the configuration of one embodiment. In addition, it is possible to perform addition, deletion, and replacement with respect to a part of the configuration of each embodiment.

According to the present disclosure in some embodiments, it is possible to protect a pipe of an exhaust system against over-pressurization.

While certain embodiments are described above, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An exhaust structure, comprising:
an exhaust pipe configured to exhaust an atmosphere of a process chamber;
a regulator installed on the exhaust pipe and configured to regulate a pressure inside the process chamber;
a vent pipe installed to be branched off from the exhaust pipe at an upstream of the regulator;
a pressure detector installed on the exhaust pipe at a downstream of the regulator and configured to detect the pressure inside the exhaust pipe; and
a branch pipe including an opening/closing part configured to operate in response to a signal from the pressure detector, the branch pipe branching off from the exhaust pipe at the downstream of the regulator,
wherein the branch pipe is configured to be connected to the vent pipe.

2. The exhaust structure of claim 1, wherein when the pressure detector detects a preset pressure, the opening/closing part is configured to be switched from a closed state to an open state.

3. The exhaust structure of claim 1, wherein the pressure detector is configured to detect an atmospheric pressure.

4. The exhaust structure of claim 1, further comprising a purge pipe connected to the exhaust pipe and configured to supply a gas to the exhaust pipe, and
wherein the branch pipe is configured to be connected to the exhaust pipe at a position separated from a portion of the exhaust pipe that is connected to the purge pipe.

5. The exhaust structure of claim 4, wherein the purge pipe is configured to be installed at a downstream of the branch pipe.

6. The exhaust structure of claim 4, further comprising:
a first opening/closing part installed on the exhaust pipe at an upstream of a portion of the exhaust pipe that is connected to the purge pipe, and configured to be able to cut off communication with the process chamber.

7. The exhaust structure of claim 4, further comprising:
a second opening/closing part installed on the exhaust pipe at a downstream of a portion of the exhaust pipe that is connected to the purge pipe, and configured to be capable of stopping evacuation of the exhaust pipe.

8. The exhaust structure of claim 6, wherein the vent pipe is configured to be branched off from the exhaust pipe at an upstream of the first opening/closing part.

9. The exhaust structure of claim 1, wherein the branch pipe includes a valve configured to prevent backflow into the exhaust pipe.

10. The exhaust structure of claim 1, wherein an exhaust configured to reduce the pressure inside the process chamber is installed at a downstream of a portion of the exhaust pipe to which the branch pipe is connected.

11. The exhaust structure of claim 7, wherein an exhaust device configured to reduce the pressure inside the process chamber is installed, and
wherein the second opening/closing part is installed at a downstream of the exhaust device.

12. The exhaust structure of claim 4, wherein the purge pipe includes a heater configured to heat the gas.

13. The exhaust structure of claim 6, further comprising:
a flow rate controller configured to control the flow rate of the gas,
wherein the purge pipe is configured to supply the gas of which the flow rate is controlled by the flow rate controller to the exhaust pipe while the first opening/closing part and the opening/closing part are in a closed state.

14. The exhaust structure of claim 7, further comprising:
a flow rate controller configured to control the flow rate of the gas,
wherein the purge pipe is configured to supply the gas of which the flow rate is controlled by the flow rate controller to the exhaust pipe while the second opening/closing part and the opening/closing part are in a closed state.

15. The exhaust structure of claim 14, wherein the flow rate of the gas flowing through the flow rate controller is configured to converge from a preset flow rate to zero within a predetermined time.

16. An exhaust system, comprising:
the exhaust structure of claim 1; and
a controller configured to be capable of controlling the pressure detector and the opening/closing part to open the opening/closing part when the pressure inside the exhaust pipe exceeds an atmospheric pressure.

17. A processing apparatus, comprising:
an exhaust structure,
wherein the exhaust structure includes:
an exhaust pipe configured to exhaust an atmosphere of a process chamber;
a regulator installed on the exhaust pipe and configured to regulate a pressure inside the process chamber;
a vent pipe installed to be branched off from the exhaust pipe at an upstream of the regulator;
a pressure detector installed on the exhaust pipe at a downstream of the regulator and configured to detect the pressure inside the exhaust pipe; and
a branch pipe including an opening/closing part configured to operate in response to a signal from the pressure detector, the branch pipe branching off from the exhaust pipe at the downstream of the regulator,
wherein the branch pipe is configured to be connected to the vent pipe.

18. A method of manufacturing a semiconductor device, comprising:
processing a substrate using an exhaust structure while evacuating a process chamber,
wherein the exhaust structure includes:
an exhaust pipe configured to exhaust an atmosphere of the process chamber;
a regulator installed on the exhaust pipe and configured to regulate a pressure inside the process chamber;
a vent pipe installed to be branched off from the exhaust pipe at an upstream of the regulator;
a pressure detector installed on the exhaust pipe at a downstream of the regulator and configured to detect the pressure inside the exhaust pipe; and
a branch pipe including an opening/closing part configured to operate in response to a signal from the pressure detector, the branch pipe branching off from the exhaust pipe at the downstream of the regulator, and
wherein the branch pipe is configured to be connected to the vent pipe.
